(19) United States
(12) Patent Application Publication
(10) Pub. No.: US 2025/0227872 A1
(43) Pub. Date: Jul. 10, 2025

(54) COOLING SYSTEM

(71) Applicant: TOYOTA JIDOSHA KABUSHIKI KAISHA, TOYOTA-SHI (JP)

(72) Inventor: Akihiro SATO, Okazaki-shi (JP)

(73) Assignee: TOYOTA JIDOSHA KABUSHIKI KAISHA, TOYOTA-SHI (JP)

(21) Appl. No.: 18/912,603

(22) Filed: Oct. 11, 2024

(30) Foreign Application Priority Data
Jan. 10, 2024 (JP) 2024-001704

(51) Int. Cl. H05K 7/20

(52) U.S. Cl. CPC H05K 7/20145; H05K 7/20409; H05K 7/20918

(57) ABSTRACT

A cooling system includes: a blower; a metal case; a semiconductor module housed in the metal case and disposed on a lower surface of an upper wall of the metal case; and a resin duct disposed so as to cover at least part of an upper surface of the upper wall of the metal case, and configured to guide cooling air from the blower along the upper surface of the upper wall between an upstream end of the resin duct that is connected to the blower and a downstream end of the resin duct that is open to outside. The resin duct includes a first resin portion made of a thermoplastic resin, and a second resin portion made of a thermosetting resin. The second resin portion of the resin duct is located above the semiconductor module and is supported by the first resin portion.

### CROSS-REFERENCE TO RELATED APPLICATION

This application claims priority to Japanese Patent Application No. 2024-001704 filed on Jan. 10, 2024, incorporated herein by reference in its entirety.

### BACKGROUND

### 1. Technical Field

The technique disclosed in the present specification relates to cooling systems.

### 2. Description of Related Art

Japanese Unexamined Patent Application Publication No. 2010-41809 (JP 2010-41809 A) discloses a cooling system that includes: a metal case; semiconductor modules housed in the metal case and disposed on the lower surface of an upper wall of the metal case; and a coolant channel provided on the upper wall side of the metal case. In this cooling system, a coolant flowing through the coolant channel cools the semiconductor modules in the metal case.

### SUMMARY

There is a cooling system having a configuration in which a semiconductor module in a metal case is cooled by air instead of a coolant (i.e., an air cooling type cooling system). In such a configuration, the semiconductor module may overheat when an abnormality occurs in the semiconductor module. In this case, the metal case may melt and a hole may be formed in the metal case. When there is a hole in the metal case, foreign matter may enter the metal case through the hole.

The present specification provides a technique that can reduce entry of foreign matter into a metal case.

A cooling system according to a first aspect of the present technique includes:
a blower;
a metal case;
a semiconductor module housed in the metal case and disposed on a lower surface of an upper wall of the metal case; and
a resin duct disposed so as to cover at least part of an upper surface of the upper wall of the metal case, and configured to guide cooling air from the blower along the upper surface of the upper wall between an upstream end of the resin duct that is connected to the blower and a downstream end of the resin duct that is open to outside.

The resin duct includes a first resin portion made of a thermoplastic resin, and a second resin portion made of a thermosetting resin.

The second resin portion of the resin duct is located above the semiconductor module and is supported by the first resin portion.

As described above, when the semiconductor module overheats, the metal case may melt and a hole may be formed in the metal case. In this case, a hot gas flows out of the metal case through the hole. In the above configuration, the first resin portion of the resin duct that is made of a thermoplastic resin is melted by the gas flowing out of the metal case through the hole. However, the second resin portion made of a thermosetting resin does not melt. When the first resin portion melts, the second resin portion located above the semiconductor module falls, so that the hole of the metal case can be at least partially covered. It is therefore possible to reduce entry of foreign matter into the metal case.

According to a second aspect, in the first aspect,
a plurality of fins may be provided on the upper surface of the upper wall of the metal case. The fins may extend in a first direction from the upstream end toward the downstream end and may be arranged in a second direction perpendicular to the first direction.

The second resin portion may include a plurality of resin extension portions extending in the first direction and arranged in the second direction.

Each of the resin extension portions may be disposed above two adjacent ones of the fins.

In the above configuration, when the semiconductor module overheats, a hole is expected to be formed between two of the fins that are adjacent to each other in the second direction. In this regard, the above configuration can more reliably cause the resin extension portion of the second resin portion to fall between the two adjacent fins when the first resin portion melts and the resin extension portion falls. It is therefore possible to more reliably cover the hole formed by melting of the upper wall.

According to a third aspect, in the second aspect,
both ends of the resin extension portion may be located outward of both ends of the semiconductor module in the first direction.

Melting of the metal case is caused by overheating of the semiconductor module. Therefore, when the upper wall of the metal case melts and a hole is formed in the upper wall, this hole is expected to be formed in the range in which the semiconductor module is located. Therefore, when both ends of the resin extension portion are located outward of both ends of the semiconductor module in the first direction, the hole formed by melting of the upper wall can be more reliably covered.

In a fourth aspect, in the second or third aspect,
two of the resin extension portions that are located at both sides may be located outward of the semiconductor module in the second direction.

As described above, when the upper wall of the metal case melts and a hole is formed in the upper wall, this hole is expected to be formed in the range in which the semiconductor module is located. Therefore, when two of the resin extension portions that are located at both sides are located outward of the semiconductor module in the second direction, the hole formed by melting of the upper wall can be more reliably covered.

In a fifth aspect, in any of the first to fourth aspects,
the thermoplastic resin may be polypropylene, and the thermosetting resin may be a phenolic resin.

With the above configuration, it is possible to reliably cause the first resin portion to melt while maintaining the shape of the second resin portion at the temperature expected to be reached when the upper wall of the metal case melts. It is therefore possible to more reliably cover the hole formed by melting of the upper wall.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a perspective view of a cooling system 2;

FIG. 2 is a front cross-sectional view of the cooling system 2;

FIG. 3 is a top view of the cooling system 2;

FIG. 4A is a diagram illustrating a case in which the semiconductor module 44A is overheated

FIG. 4B illustrates a continuation of FIG. 4A;

FIG. 5A illustrates a continuation of FIG. 4B; and

FIG. 5B illustrates a continuation of FIG. 5A;

### DETAILED DESCRIPTION OF EMBODIMENTS

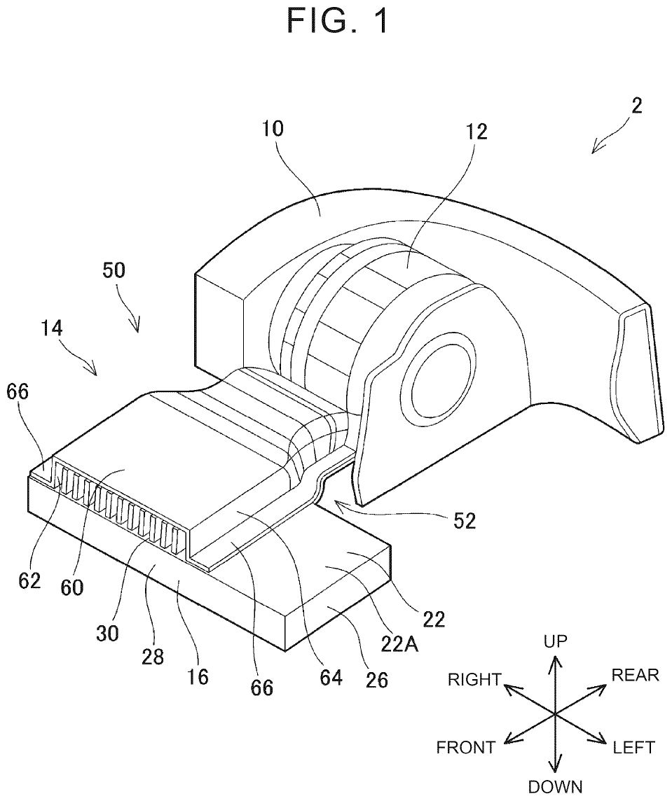

As shown in FIG. 1, the cooling system 2 includes an intake duct 10, a blower 12, an exhaust duct 14, and a converter case 16. The cooling system 2 is mounted on a electrified vehicle. Electrified vehicle is, for example, a battery electric vehicle in which a drive motor is rotated by a battery, a fuel cell electric vehicle in which a drive motor is rotated by electric power generated by a fuel cell, or a hybrid electric vehicle including both a drive motor and an internal combustion engine. Hereinafter, for ease of understanding, the extending direction of the exhaust duct 14 is referred to as a “front-rear direction”, and the “left-right direction” and the “up-down direction” are defined as shown in FIG. 1 with reference thereto. Note that the “front-rear direction” and the “left-right direction” defined here do not limit the posture when the cooling system 2 is used.

### Configuration of Converter Case 16

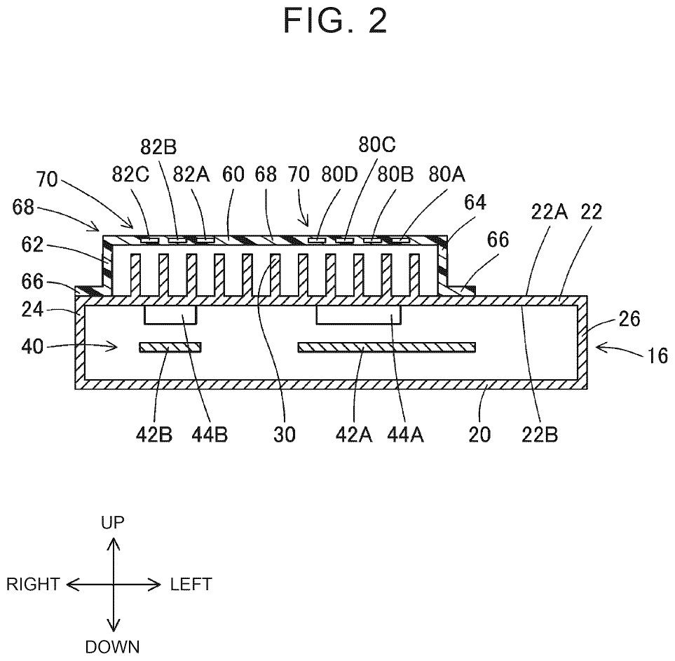

The converter case 16 is a metal case. The converter case 16 includes a case bottom wall 20 (see FIG. 2), a case upper wall 22, a case right wall 24 (see FIG. 2), a case left wall 26, a case front wall 28, and a case rear wall (not shown). A plurality of fins 30 extending in the front-rear direction are provided on the upper surface 22A of the case upper wall 22. The plurality of fins 30 are arranged side by side in the left-right direction. The plurality of fins 30 are arranged at equal intervals in the left-right direction.

As shown in FIG. 2, DC-DC converter 40 is housed in the converter case 16. It should be noted that DC-DC converters 40 are shown in simplified form in FIG. 2. The DC-DC converters 40 includes a plurality of circuit-board 42A, 42B and a plurality of semiconductor modules 44A, 44B. The plurality of semiconductor modules 44A, 44B is attached to the lower surface 22B of the case upper wall 22 of the converter case 16.

### Configuration of Intake Duct 10

The upstream end of the intake duct 10 of FIG. 1 is open to the outside, and the downstream end of the intake duct 10 is connected to the blower 12. The blower 12 sucks the cooling air through the intake duct 10 and delivers the cooling air to the exhaust duct 14.

### Configuration of Exhaust Duct 14

The exhaust duct 14 is a resin duct. The exhaust duct 14 extends in the front-rear direction. An upstream end (i.e., a rear end) of the exhaust duct 14 is connected to the blower 12, and a downstream end (i.e., a front end) of the exhaust duct 14 is open to the outside. The exhaust duct 14 is disposed so as to cover a part of the upper surface 22A of the case upper wall 22 of the converter case 16. Specifically, the exhaust duct 14 covers the upper surface 22A of the case upper wall 22 in the area where the semiconductor modules 44A, 44B are disposed. The exhaust duct 14 guides the cooling air from the blower 12 along the upper surface 22A between the upstream end and the downstream end.

The exhaust duct 14 includes an upper duct portion 50 and a lower duct portion 52. The upper duct portion 50 extends from the upstream end to the downstream end. An upstream end (i.e., a rear end) of the upper duct portion 50 is connected to the intake duct 10. The position of the downstream end (that is, the front end) of the upper duct portion 50 in the front-rear direction substantially coincides with the front end of the converter case 16. The lower duct portion 52 is provided between the intake duct 10 and the converter case 16. The lower duct portion 52 is fixed to the upper duct portion 50 from below by screws (not shown) or the like.

The upper duct portion 50 includes a duct upper wall 60, a duct right wall 62, a duct left wall 64, and side edges 66 provided on both left and right sides of the upper duct portion 50. The right side edge 66 extends rightward from the lower end of the duct right wall 62, and the left side edge 66 extends leftward from the lower end of the duct left wall 64. As shown in FIG. 2, the upper duct portion 50 includes a first resin portion 68 made of a thermoplastic resin and a second resin portion 70 made of a thermosetting resin. By way of example, the thermoplastic resin is polypropylene and the thermosetting resin is a phenolic resin. The duct right wall 62, the duct left wall 64, and the side edge 66 are constituted by the first resin portion 68. The duct upper wall 60 includes a first resin portion 68 and a second resin portion 70. In FIG. 2, a portion including the first resin portion 68 is hatched, and a portion including the second resin portion 70 is not hatched. Although not shown, the duct right wall 62 and the duct left wall 64 are fixed to the converter case 16 by screws or the like. The second resin portion 70 includes a plurality of left side resin extension portions 80A to 80D and a plurality of right side resin extension portions 82A to 82C. Hereinafter, the plurality of left side resin extension portions 80A to 80D and the plurality of right side resin extension portions 82A to 82C may be collectively referred to as “left side resin extension portions 80” and “right side resin extension portions 82”. The left side resin extension portions 80 and the right side resin extension portions 82 are supported by the first resin portion 68. In the present embodiment, the left side resin extension portions 80 and the right side resin extension portions 82 are embedded in the first resin portion 68. In the modified example, the left side resin extension portions 80 and the right side resin extension portions 82 may be provided on the upper surface of the first resin portion 68, or may be adhered to the lower surface of the first resin portion 68 by an adhesive or the like.

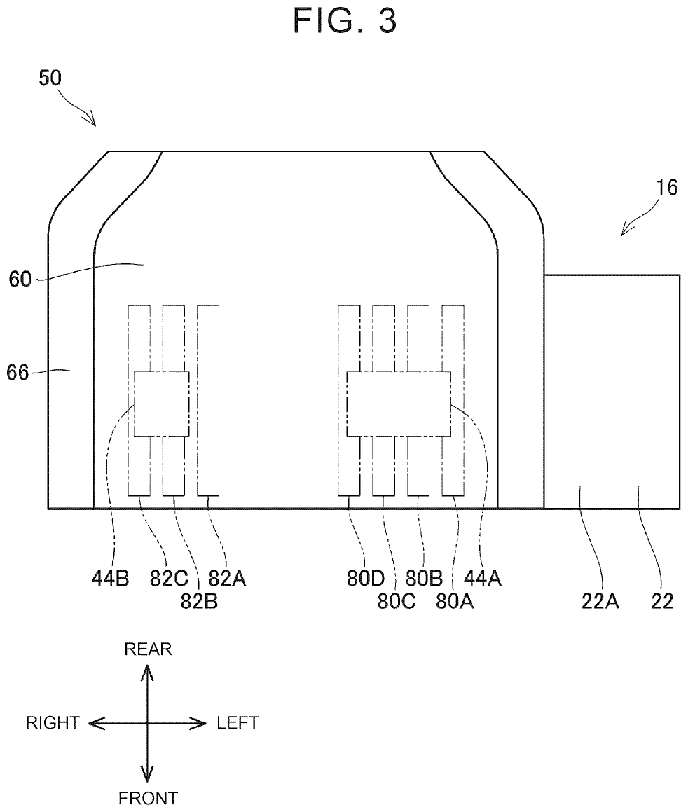

The plurality of left side resin extension portions 80A to 80D is disposed above the semiconductor module 44A. The plurality of left side resin extension portions 80A to 80D are arranged at equal intervals in the left-right direction. In the left-right direction, each of the plurality of left side resin extension portions 80A to 80D is disposed between two adjacent fins 30. The length of the left side resin extension portions 80 in the left-right direction is slightly shorter than the distance between two adjacent fins 30 in the left-right direction. The length of the left side resin extension portions 80 in the left-right direction may be shorter than the distance between two adjacent fins 30. The left end of the left side resin extension portion 80A disposed on the leftmost side is located on the left side relative to the left ends of the semiconductor module 44A. The right end of the left side resin extension portion 80D disposed on the rightmost side is located on the right side of the right end portion of the semiconductor module 44A. Referring to FIG. 3, the left side resin extension portions 80 will be described. In FIG. 3, the semiconductor modules 44A, 44B, the left side resin extension portions 80, and the right side resin extension portions 82 are indicated by two-dot chain lines for ease of understanding. As shown in FIG. 3, the front and rear ends of the left side resin extension portions 80 are located outward of the front and rear ends of the semiconductor module 44A. That is, the length of the left side resin extension portions 80 in the front-rear direction is longer than the length of the semiconductor module 44A in the front-rear direction.

As shown in FIG. 2, the plurality of right side resin extension portions 82A to 82C are disposed above the semiconductor module 44B. The plurality of right side resin extension portions 82A to 82C are arranged at equal intervals in the left-right direction. In the left-right direction, each of the plurality of right side resin extension portions 82A to 82C is disposed between two adjacent fins 30. The length of the right side resin extension portions 82 in the left-right direction is slightly shorter than the distance between two adjacent fins 30. The left end portion of the right side resin extension portion 82A disposed on the leftmost side is located on the left side of the left end portion of the semiconductor module 44B. The right end portion of the right side resin extension portion 82C disposed on the rightmost side is located on the right side of the right end portion of the semiconductor module 44B. As shown in FIG. 3, the front and rear ends of the right side resin extension portions 82 are located outward of the front and rear ends of the semiconductor module 44B. That is, the length of the right side resin extension portions 82 in the front-rear direction is longer than the length of the semiconductor module 44B in the front-rear direction. In the present embodiment, the shapes and sizes of the left side resin extension portions 80 and the right side resin extension portions 82 are the same, but in the modification, the shapes and sizes of the left side resin extension portions 80 and the right side resin extension portions 82 may be different.

### Effects of First Resin Portion 68 and Second Resin Portion 70

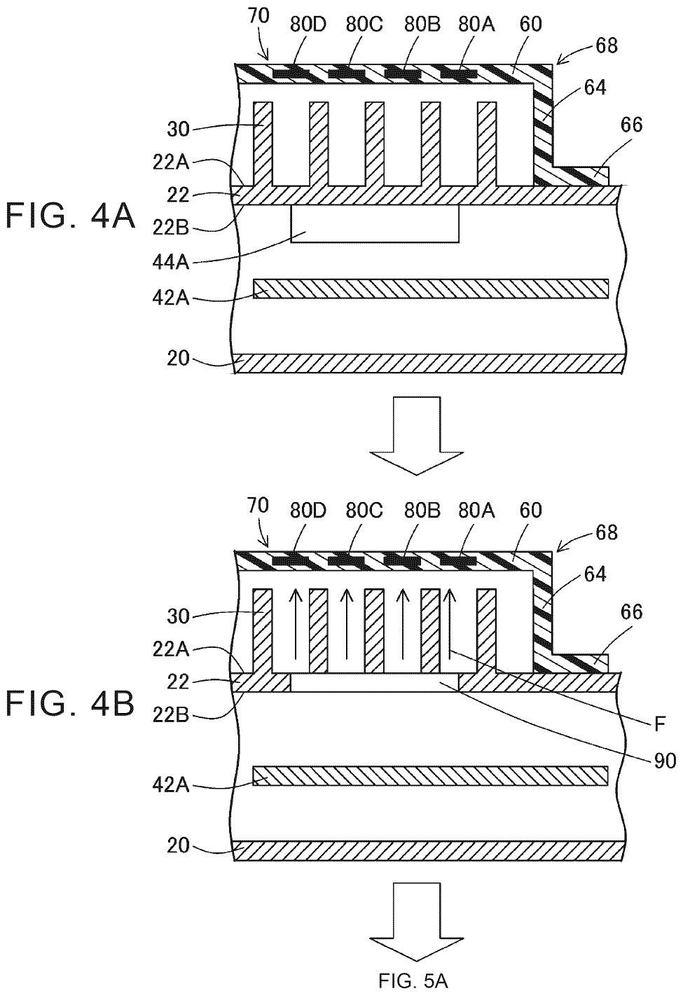

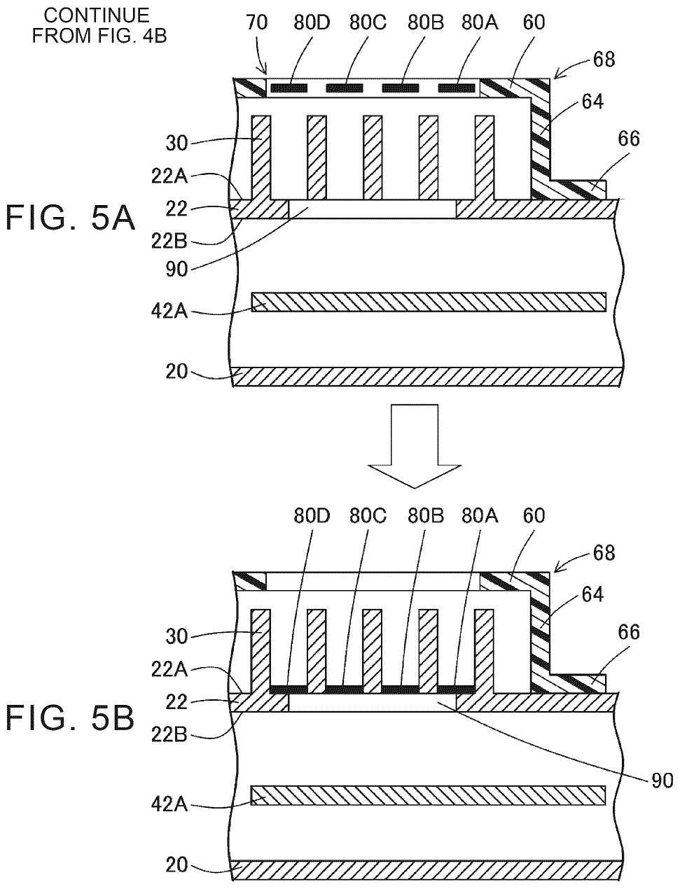

The advantages of the first resin portion 68 and the second resin portion 70 will be described with reference to FIGS. 4A, 4B and FIGS. 5A, 5B. In FIGS. 4A, 4B and FIGS. 5A, 5B, it is assumed that the semiconductor module 44A is damaged in response to overheating of the semiconductor module 44A. FIG. 4A shows a condition immediately before the semiconductor module 44A melts. In FIGS. 4A, 4B and FIGS. 5A, 5B, the left side resin extension portions 80 and the right side resin extension portions 82 are shown in gray.

As shown in FIG. 4B, the semiconductor module 44A melts in response to overheating of the semiconductor module 44A. In addition, a part of the case upper wall 22 of the converter case 16 that is contacted by the semiconductor module 44A melts. As a result, a hole 90 is formed in the case upper wall 22 of the converter case 16 so as to communicate the outside with the inside of the converter case 16. Then, the hot gases pass through the hole 90 and rise (arrow F in FIG. 4B).

As shown in FIG. 5A, when the hot gases reach the duct upper wall 60 of the upper duct portion 50, part (i.e., a thermoplastic resin) constituted by the first resin portion 68 of the duct upper wall 60 is melted. On the other hand, a portion of the duct upper wall 60 composed of the second resin portion 70 (that is, the thermosetting resin) does not melt. As a result, the plurality of left side resin extension portions 80A to 80D of the second resin portion 70 is not supported by the first resin portion 68, and drops from the plurality of left side resin extension portions 80A to 80D.

As illustrated in FIG. 5B, the plurality of dropped left side resin extension portions 80A to 80D are placed on the upper surface 22A of the case upper wall 22 of the converter case 16. That is, the hole 90 formed by the melting of the case upper wall 22 is blocked by the plurality of left side resin extension portions 80A to 80D. Therefore, it is possible to reduce entry of (conductive) foreign matter the converter case 16 through the hole 90.

### Effect of Embodiment

As described above, as shown in FIGS. 1 to 3, a cooling system 2, a blower 12, a converter case 16, a semiconductor module 44A, and an exhaust duct 14 are provided. The converter case 16 is an example of a “metal case”. The semiconductor module 44A is housed in the converter case 16 and is disposed on the lower surface 22B of the case upper wall 22 of the converter case 16. The exhaust duct 14 is an example of a “resin duct”. The exhaust duct 14 is disposed so as to cover at least a part of the upper surface 22A of the case upper wall 22 of the converter case 16, and guides the cooling air from the blower 12 along the upper surface 22A of the case upper wall 22 between an upstream end connected to the blower 12 and a downstream end open to the outside. The exhaust duct 14 includes a first resin portion 68 made of a thermoplastic resin and a second resin portion 70 made of a thermosetting resin. The second resin portion 70 of the exhaust duct 14 is positioned above the semiconductor modules 44A, 44B and is supported by the first resin portion 68.

As shown in FIGS. 4A, 4B and FIGS. 5A, 5B, when the semiconductor module 44A is overheated, the converter case 16 may melt and the hole 90 may be opened in the converter case 16. In this case, the hot gas flows out from the hole 90 of the converter case 16. According to the above configuration, the first resin portion 68 made of the thermoplastic resin in the exhaust duct 14 is melted by the gas flowing out of the hole 90 of the converter case 16. On the other hand, the second resin portion 70 made of the thermosetting resin does not melt. As the first resin portion 68 melts, the second resin portion 70 located above the semiconductor module 44A falls, and the hole 90 of the converter case 16 can be at least partially covered. Therefore, it is possible to suppress intrusion of foreign matter into the converter case 16.

Further, as shown in FIG. 1, on the upper surface 22A of the case upper wall 22 of the converter case 16, a plurality of fins 30 each extending along the front-rear direction from the upstream end toward the downstream end and arranged along the left-right direction are provided. The front-rear direction is an example of the “first direction”. The left-right direction is an example of the “second direction”. As shown in FIG. 2, the second resin portion 70 includes a plurality of left side resin extension portions 80 each extending along the front-rear direction and arranged along the left-right direction. Each of the plurality of left side resin extension portions 80 is disposed above two adjacent ones of the plurality of fins 30.

In the above-described configuration, when the semiconductor module 44A is overheated, it is assumed that the hole 90 is formed between two adjacent fins 30. In this regard, according to the above configuration, when the first resin portion 68 melts and the left side resin extension portions 80 of the second resin portion 70 falls, the left side resin extension portions 80 can be more reliably dropped between the two adjacent fins 30. Therefore, the hole 90 formed by the melting of the case upper wall 22 can be more reliably covered.

As shown in FIG. 3, both ends of the left side resin extension portions 80 are located outward of both ends of the semiconductor module 44A.

The melting of the converter case 16 is caused by the overheating of the semiconductor module 44A. Therefore, when the case upper wall 22 of the converter case 16 melts and the hole 90 is formed in the case upper wall 22, it is assumed that the hole 90 is formed within the area where the semiconductor module 44A is disposed. Therefore, when both ends of the left side resin extension portions 80 are located outward of both ends of the semiconductor module 44A in the front-rear direction, the hole 90 formed by melting of the case upper wall 22 can be more reliably covered.

As shown in FIG. 2, two of the resin extension portions 80 that are located at both sides are located outward of the semiconductor module 44A in the left-right direction.

When two of the left side resin extension portions 80 that are located at both ends are located outward of the semiconductor module 44A in the front-rear direction, the hole 90 formed by the melting of the case upper wall 22 can be more reliably covered.

The thermoplastic resin is polypropylene, and the thermosetting resin is a phenolic resin.

With the above configuration, it is possible to reliably cause the first resin portion 68 to melt while maintaining the shape of the second resin portion 70 at the temperature expected to be reached when the case upper wall 22 of the converter case 16 melts. Thus, the hole 90 formed by the melting of the case upper wall 22 can be more reliably covered.

Although the specific examples disclosed by the present disclosure have been described in detail above, these are merely examples and do not limit the scope of claims. The techniques described in the claims include various modifications and alternations of the specific examples illustrated above.

### First Modification

The fins 30 may not be provided on the case upper wall 22 of the converter case 16. In this modification, the size of the cross-sectional shape perpendicular to the vertical direction of the second resin portion 70 is larger than the size of the cross-sectional shape of the semiconductor module 44A. In another modification, in a configuration in which the fins 30 are not provided on the case upper wall 22 of the converter case 16, the size of the cross-sectional shape perpendicular to the vertical direction of the second resin portion 70 may be smaller than the size of the cross-sectional shape of the semiconductor module 44A.

### Second Modification

At least one of the front and rear ends of the left side resin extension portions 80 may be located inward of the front and rear ends of the semiconductor module 44A.

### Third Modification

The second resin portion 70 may not include at least one of the left side resin extension portion 80A located on the leftmost side and the left side resin extension portion 80D located on the rightmost side.

### Fourth Modification

The right side resin extension portions 82 may not be provided above the semiconductor module 44B.

### Fifth Modification

The “thermoplastic resin” and the “thermosetting resin” are not limited to polypropylene and phenolic resins, respectively.

In addition, the technical elements described in this specification or in the drawings may be used alone or in various combinations, and are not limited to the combinations described in the claims at the time of filing. In addition, the techniques illustrated in the present specification or drawings can achieve a plurality of objectives at the same time, and achieving one of the objectives itself has technical usefulness.

What is claimed is:

1. A cooling system, comprising:
a blower;
a metal case;
a semiconductor module housed in the metal case and disposed on a lower surface of an upper wall of the metal case; and
a resin duct disposed so as to cover at least part of an upper surface of the upper wall of the metal case, and configured to guide cooling air from the blower along the upper surface of the upper wall between an upstream end of the resin duct that is connected to the blower and a downstream end of the resin duct that is open to outside, wherein
the resin duct includes a first resin portion made of a thermoplastic resin, and a second resin portion made of a thermosetting resin, and
the second resin portion of the resin duct is located above the semiconductor module and is supported by the first resin portion.

2. The cooling system according to claim 1, wherein:
a plurality of fins is provided on the upper surface of the upper wall of the metal case, the fins extending in a first direction from the upstream end toward the downstream end and arranged in a second direction perpendicular to the first direction;
the second resin portion includes a plurality of resin extension portions extending in the first direction and arranged in the second direction; and
each of the resin extension portions is disposed above two adjacent ones of the fins.

3. The cooling system according to claim 2, wherein both ends of the resin extension portion are located outward of both ends of the semiconductor module in the first direction.

4. The cooling system according to claim 3, wherein two of the resin extension portions that are located at both sides are located outward of the semiconductor module in the second direction.

5. The cooling system according to claim 1, wherein:
the thermoplastic resin is polypropylene; and
the thermosetting resin is a phenolic resin.
